(19) United States
(12) Patent Application Publication
(10) Pub. No.: US 2021/0367291 A1
(43) Pub. Date: Nov. 25, 2021

(54) HEAT TRANSFER MEDIUM AND HEAT TRANSFER SYSTEM

(71) Applicants: DENSO CORPORATION, Kariya-city (JP); TANIKAWAYUKA KOGYO CO., LTD., Yokohama-shi (JP)

(72) Inventors: Takuya FUSE, Kariya-city (JP); Teru YAMADA, Yokohama-shi (JP); Kazumi SUZUKI, Yokohama-shi (JP)

(21) Appl. No.: 17/394,046

(22) Filed: Aug. 4, 2021

Related U.S. Application Data
(63) Continuation of application No. PCT/JP2020/004572, filed on Feb. 6, 2020.

(30) Foreign Application Priority Data
Feb. 8, 2019 (JP) 2019-021282

(51) Int. Cl. H01M 10/6568; H01M 10/613; H01M 10/6569; C09K 5/10

(52) U.S. Cl. CPC H01M 10/6568; H01M 10/613; B60H 1/00278; C09K 5/10; H01M 10/6569

(57) ABSTRACT

A heat transfer medium is used for a heat transfer system including a refrigerant cycle device through which a refrigerant circulates and a heat transfer medium circuit having a cooling target device. The heat transfer medium is cooled through heat exchange with the refrigerant and absorbs heat from the cooling target device while circulating through the heat transfer medium circuit. The heat transfer medium includes a carboxylate aqueous solution formed by dissolving carboxylate in water. Accordingly, by using the carboxylate aqueous solution as the heat transfer medium, a low viscosity at a low temperature can be secured. Further, since the carboxylate aqueous solution has a high heat exchange efficiency, the cooling capacity of the heat transfer medium can be improved.

### CROSS REFERENCE TO RELATED APPLICATIONS

This application is a continuation application of International Patent Application No. PCT/JP2020/004572 filed on Feb. 6, 2020, which designated the U.S. and claims the benefit of priority from Japanese Patent Application No. 2019-021282 filed on Feb. 8, 2019. The entire disclosure of all of the above application is incorporated herein by reference.

### TECHNICAL FIELD

The present disclosure relates to a heat transfer medium and a heat transfer system.

### BACKGROUND ART

A device that cools a low-temperature cooling water by exchanging heat between a refrigerant of a refrigeration cycle system and the low-temperature cooling water in a low-temperature cooling water circuit at a chiller has been known. In this device, an ethylene glycol aqueous solution or the like is used as the low-temperature cooling water.

### SUMMARY

According to a first aspect of the present disclosure, a heat transfer medium is used for a heat transfer system including a refrigerant cycle device through which a refrigerant circulates and a heat transfer medium circuit having a cooling target device. The medium includes a carboxylate aqueous solution formed by dissolving carboxylate in water. The carboxylate aqueous solution is cooled through heat exchange with the refrigerant and absorbs heat from the cooling target device while circulating through the heat transfer medium circuit.

According to a second aspect of the present disclosure, a heat transfer system includes a heat transfer medium circuit through which the heat transfer medium circulates, a refrigeration cycle device, and a cooling target device. A refrigerant circulates through the refrigeration cycle device. The cooling heat exchanger cools the heat transfer medium through heat exchange between the refrigerant and the heat transfer medium. The cooling target device is disposed in the heat transfer medium circuit, the heat transfer medium absorbing heat from the cooling target device.

### BRIEF DESCRIPTION OF DRAWINGS

FIG. 1 is a diagram showing one example of a heat transfer system according to the present disclosure.

FIG. 2 is a diagram showing a positional relationship between a battery and a cooler.

FIG. 3 is a graph showing a heat exchange efficiency of an carboxylate aqueous solution.

### DESCRIPTION OF EMBODIMENTS

To begin with, a relevant technology will be described first only for understanding the following embodiment. Since the ethylene glycol aqueous solution has a high viscosity at a low temperature, the pressure loss in the low temperature cooling water circuit may increase. Therefore, the pumping power for circulating the low-temperature cooling water has to be increased. In addition, when an electric device such as a battery is cooled by a low-temperature cooling water, water exposure measures such as a measure to house the electric device in a case may be taken to prevent electric leakage. However, if such measures against water exposure are taken, the heat transfer resistance would increase, and thus the cooling capacity of the low-temperature cooling water would become insufficient.

In view of the above, it is an objective of the present disclosure to suppress an increase in viscosity of the heat transfer medium at a low temperature and to secure cooling capacity of the heat transfer medium.

As described above, according to the first aspect of the present disclosure, a heat transfer medium is used for a heat transfer system including a refrigerant cycle device through which a refrigerant circulates and a heat transfer medium circuit having a cooling target device. The medium includes a carboxylate aqueous solution formed by dissolving carboxylate in water. The carboxylate aqueous solution is cooled through heat exchange with the refrigerant and absorbs heat from the cooling target device while circulating through the heat transfer medium circuit.

As described above, according to the second aspect of the present disclosure, a heat transfer system includes a heat transfer medium circuit through which the heat transfer medium circulates, a refrigeration cycle device, and a cooling target device. A refrigerant circulates through the refrigeration cycle device. The cooling heat exchanger cools the heat transfer medium through heat exchange between the refrigerant and the heat transfer medium. The cooling target device is disposed in the heat transfer medium circuit, the heat transfer medium absorbing heat from the cooling target device.

Accordingly, by using the carboxylate aqueous solution as the heat transfer medium, a low viscosity at a low temperature can be secured. Therefore, even under a low-temperature environment, an increase in pressure loss in the heat medium circuit can be suppressed, and an increase in pumping power can be suppressed.

Further, since the carboxylate aqueous solution has a high heat exchange efficiency, the cooling by the heat transfer medium can be improved. Therefore, the required cooling capacity can be secured even under a configuration that causes the heat transfer resistance to increase such as a configuration where the electric device exchanges heat with the heat transfer medium via a partition wall.

Hereinafter, a most suitable embodiment to which the heat transfer system of the present disclosure is applied will be described with reference to the drawings.

The heat transfer system 1 of the present embodiment is mounted in an electric vehicle that obtains a driving force for traveling the vehicle from a traveling electric motor. Alternatively, the heat transfer system 1 of the present embodiment may be mounted in a hybrid car which obtains a driving force for traveling of the vehicle from both an engine (i.e., an internal combustion engine) and a traveling electric motor. The heat transfer system 1 of the present embodiment serves as an air-conditioner for adjusting the temperature in a vehicle interior, and also serves as a temperature control device for adjusting the temperature of the battery 33 or the like mounted in the vehicle.

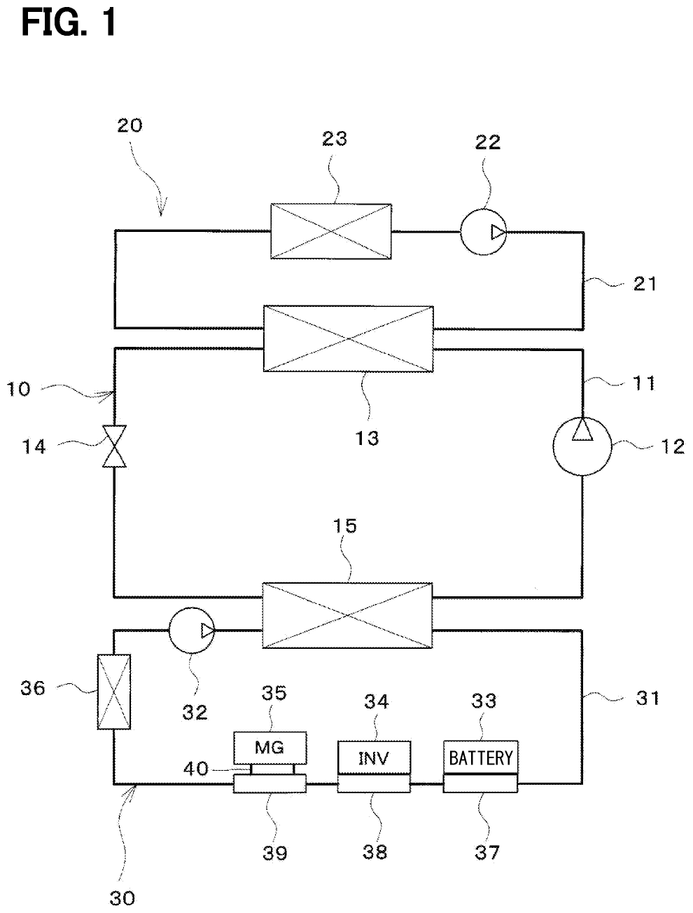

As shown in FIG. 1, the heat transfer system 1 includes a refrigeration cycle device 10, a high-temperature medium circuit 20, and a low-temperature medium circuit 30. In the high-temperature medium circuit 20 and the low-temperature medium circuit 30, heat is transferred through the heat transfer medium. The heat transfer medium in the low-temperature medium circuit 30 has a lower temperature than the heat transfer medium in the high-temperature medium circuit 20. Thereafter, the heat transfer medium in the high-temperature medium circuit 20 may be also referred to as a high-temperature heat transfer medium, and the heat transfer medium in the low-temperature medium circuit 30 is also referred to as a low-temperature heat transfer medium. The high temperature medium circuit 20 corresponds to the high-temperature heat transfer medium circuit, and the low-temperature medium circuit 30 corresponds to the heat transfer medium circuit.

The refrigeration cycle device 10 is a vapor compression refrigerator and has a refrigerant circulation passage 11 through which a refrigerant circulates. The refrigeration cycle device 10 serves as a heat pump that pumps heat from the low-temperature heat transfer medium in the low-temperature medium circuit 30 to the refrigerant.

According to the refrigeration cycle device 10 of the present embodiment, a Freon-based refrigerant is adopted as the refrigerant to constitute a subcritical refrigeration cycle in which a high-pressure refrigerant does not exceed a critical pressure of the refrigerant. A compressor 12, a condenser 13, an expansion valve 14, and an evaporator 15 for a heat transfer medium are arranged in the refrigerant circulation passage 11. The condenser 13 corresponds to a heating heat exchanger, and the evaporator 15 for the heat transfer medium corresponds to a cooling heat exchanger.

The compressor 12 may be an electric compressor that is driven by power supplied from the battery 33. The compressor 12 is configured to draw, compress, and discharge the refrigerant. The condenser 13 is a high-pressure heat exchanger that condenses a high-pressure refrigerant by exchanging heat between the high-pressure refrigerant discharged from the compressor 12 and the heat transfer medium in a high-temperature medium circuit 20. In the condenser 13, the heat transfer medium in the high-temperature medium circuit 20 is heated by the high-pressure refrigerant in the refrigeration cycle device 10.

The expansion valve 14 serves as a decompressor that is configured to decompress and expand a liquid-phase refrigerant flowing out of the condenser 13. The expansion valve 14 is a temperature-type expansion valve having a temperature sensor and configured to move a valve element using a mechanical mechanism such as a diaphragm.

The heat transfer medium evaporator 15 is a low-pressure heat exchanger that evaporates the low-pressure refrigerant by exchanging heat between the low-pressure refrigerant flowing out of the expansion valve 14 and the heat transfer medium in the low-temperature medium circuit 30. The vapor-phase refrigerant evaporated in the heat transfer medium evaporator 15 is sucked into the compressor 12 and then is compressed.

The heat transfer medium evaporator 15 is a chiller that cools the heat transfer medium in the low-temperature medium circuit 30 with the low-pressure refrigerant in the refrigeration cycle device 10. In the heat transfer medium evaporator 15, the heat of the heat transfer medium in the low temperature medium circuit 30 is absorbed by the refrigerant of the refrigeration cycle device 10.

The high-temperature medium circuit 20 has a high-temperature circulation passage 21 in which the high-temperature heat transfer medium circulates. Ethylene glycol-based antifreeze (LLC) or the like can be used as the high-temperature heat transfer medium. The high-temperature heat transfer medium is enclosed in pipes constituting the high-temperature circulation passage 21. The high-temperature medium circuit 20 of the present embodiment is a closed-type circuit without a pressure adjusting valve that opens when the pressure of the high-temperature heat transfer medium exceeds a predetermined value.

A high-temperature pump 22, a heater core 23, and a condenser 13 are arranged in the high-temperature circulation passage 21.

The high-temperature pump 22 draws and discharges the heat transfer medium circulating through the high-temperature circulation passage 21. The high-temperature pump 22 is an electric pump. The high-temperature pump 22 adjusts the flow rate of the heat transfer medium circulating in the high-temperature medium circuit 20.

The heater core 23 is a heat exchanger for heating air. The heater core 23 is configured to perform heat exchange between the heat transfer medium in the high-temperature medium circuit 20 and air supplied into the vehicle cabin to heat the air. In the heater core 23, the air blown into the vehicle cabin is heated by the heat transfer medium.

The air heated at the heater core 23 is supplied into the vehicle cabin to heat the vehicle cabin. Heating by the heater core 23 is mainly performed in winter. In the heat transfer system of the present embodiment, heat of an outside air absorbed by the low-temperature heat transfer medium in the low-temperature medium circuit 30 is pumped up by the refrigeration cycle device 10 to the high-temperature heat transfer medium in the high-temperature medium circuit 20 and used for heating the vehicle cabin.

The low-temperature medium circuit 30 has a low-temperature circulation passage 31 in which the low-temperature heat transfer medium circulates. The low-temperature heat transfer medium is enclosed in pipes constituting the low-temperature circulation passage 31. The low-temperature medium circuit 30 of the present embodiment is a closed-type circuit without a pressure adjusting valve that opens when the pressure of the low-temperature heat transfer medium exceeds a predetermined value. Details of the low-temperature heat transfer medium will be described later.

A low-temperature pump 32, a heat transfer medium evaporator 15, a battery 33, an inverter 34, a motor generator 35, and an external heat exchanger 36 are arranged in the low-temperature circulation passage 31. In the example shown in FIG. 1, the battery 33, the inverter 34, the motor generator 35, the external heat exchanger 36, and the low-temperature pump 32 are connected to each other in this order in the flow direction of the low-temperature heat transfer medium, but the connecting order is not necessarily limited to this order. Further, in the example shown in FIG. 1, the battery 33, the inverter 34, the motor generator 35, the external heat exchanger 36, and the low-temperature pump 32 are connected to each other in series, but one or more of these devices may be connected to other devices in parallel.

The low-temperature pump 32 draws and discharges the heat transfer medium circulating in the low-temperature circulation passage 31. The low-temperature pump 32 is an electric pump. The low-temperature pump 32 adjusts the flow rate of the heat transfer medium circulating in the low-temperature medium circuit 30.

The battery 33 is a rechargeable/dischargeable secondary battery, and for example, a lithium ion battery can be used. As the battery 33, an assembled battery formed of a plurality of battery cells can be used.

The battery 33 can be charged with power supplied from an external power source (in other words, a commercial power source) when the vehicle is stopped. The power stored in the battery 33 may be supplied to the electric motor for driving the vehicle, and also be supplied to various devices, which are mounted in the vehicle, such as various electric components in the vehicle thermal management device 10.

The inverter 34 converts DC power supplied from the battery 33 into AC power and outputs it to the motor generator 35. The motor generator 35 is configured to generate a running force using the electric power output from the inverter 34 and generate regenerative electric power during deceleration or traveling downhill.

The external heat exchanger 36 exchanges heat between the heat transfer medium in the low-temperature medium circuit 30 and the outside air. The external heat exchanger 36 receives an outside air supplied from an outdoor blower (not shown).

The battery 33, the inverter 34, and the motor generator 35 are electric devices that operate using electricity and generate heat during operation. The battery 33, the inverter 34, and the motor generator 35 are cooling target devices that are cooled by the low-temperature heat transfer medium.

The low-temperature circulation passage 31 of the present embodiment is provided with coolers 37 to 39 that are disposed to serve for the electric devices 33 to 35, respectively. The first cooler 37 serves for the battery 33, the second cooler 38 serves for the inverter 34, and the third cooler 39 serves for the motor generator 35. The first cooler 37 corresponds to the cooler.

The low-temperature heat transfer medium circulates through the coolers 37 to 39. The electric devices 33 to 35 are cooled by the low-temperature heat transfer medium flowing through the coolers 37 to 39.

In the first cooler 37 and the second cooler 38, the battery 33 and the inverter 34 are directly cooled by the low-temperature heat transfer medium, respectively, without another heat transfer medium. The third cooler 39 is an oil cooler that cools an oil circulating through the oil circuit 40 by the low-temperature heat transfer medium. The oil flows inside the motor generator 35 to lubricate, and cool, the motor generator 35.

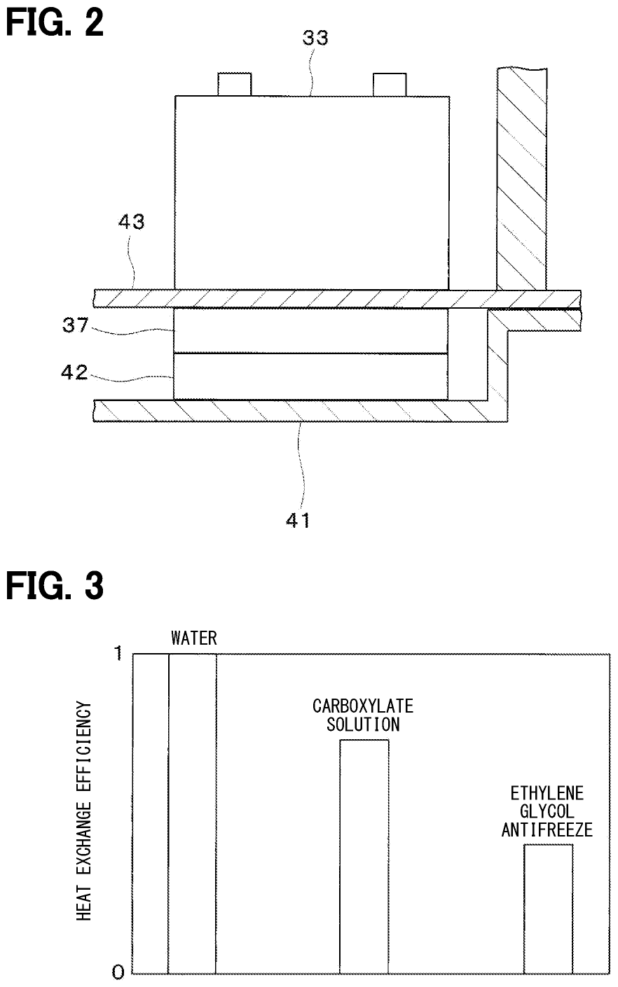

As shown in FIG. 2, the battery 33 and the first cooler 37 are housed in the case 41. The first cooler 37 is disposed on a bottom surface of the case 41 via a heat insulating member 42. The battery 33 is disposed on the first cooler 37.

A partition wall 43 is provided between the battery 33 and the first cooler 37. The partition wall 43 separates the battery 33 from the first cooler 37, and is provided as a measure against water exposure for the battery 33. The partition wall 43 can prevent the low-temperature heat transfer medium from coming into contact with the battery 33 even when the low-temperature heat transfer medium is leaked out from the first cooler 37. The heat from the battery 33 is transferred to the low-temperature heat transfer medium flowing through the first cooler 37 via the partition wall 43.

In the coolers 37 to 39, heat is transferred from the battery 33, the inverter 34, and the motor generator 35, which are cooling target devices, to the low-temperature heat transfer medium. In the external heat exchanger 36, heat is transferred from the outside air to the low-temperature heat transfer medium. That is, the battery 33, the inverter 34, the motor generator 35, and the external heat exchanger 36 are heat absorbing devices that cause the low-temperature heat transfer medium to receive heat.

Next, the low-temperature heat medium will be described. It is desirable that the low-temperature heat transfer medium has low viscosity at a low temperature and high cooling capacity.

In this embodiment, a carboxylate aqueous solution formed by dissolving a carboxylate in water is used as the low-temperature heat transfer medium. In the present embodiment, the ratio of carboxylate to water in the carboxylate aqueous solution is set as “carboxylate:water=20:80 to 50:50”.

At least one of formic acid, acetic acid, and propionic acid can be used as the carboxylic acid constituting the carboxylate. An alkali metal can be used as metal constituting the carboxylate. As the alkali metal, at least one of sodium and potassium can be used. Examples of the carboxylate include potassium formate, sodium formate, potassium acetate, sodium acetate, potassium propionate, and sodium propionate. These carboxylates may be used alone or in combination.

The potassium formate aqueous solution (45%) has a boiling point of 114° C., a kinematic viscosity at −20° C. of 5.22 mm²/s, and a kinematic viscosity at −35° C. of 10.4 mm²/s. The ethylene glycol antifreeze (LLC) as a comparative example has a kinematic viscosity of 29.6 mm²/s at −20° C. and a kinematic viscosity of 89.5 mm²/s at −35° C. Accordingly, the carboxylate aqueous solution obtains a low viscosity at a low temperature.

As shown in FIG. 3, the carboxylate aqueous solution has higher heat exchange efficiency than the ethylene glycol antifreeze solution (LLC) as the comparative example.

According to the present embodiment as described above, by using the carboxylate aqueous solution as the low-temperature heat transfer medium, it is possible to suppress an increase in viscosity under a low-temperature environment as compared to an ethylene glycol antifreeze liquid. Therefore, even under a low-temperature environment, an increase in pressure loss generated when the low-temperature heat transfer medium flows through the low-temperature medium circuit 30 can be suppressed, and an increase in power of the low-temperature pump 32 can be avoided.

Further, since the low-temperature medium circuit 30 can suppress an increase in pressure loss generated when the low-temperature heat transfer medium flows, the external heat exchanger 36 can be easily miniaturized by narrowing the passage for the low-temperature heat transfer medium. As a result, the degree of design freedom can be improved. Further, since the flow rate of the low-temperature heat transfer medium passing through the external heat exchanger 36 is increased, frost formation on the external heat exchanger 36 can be suppressed.

Further, since the increase in viscosity of the low-temperature heat transfer medium under a low-temperature environment can be suppressed, the flow rate of the low-temperature heat transfer medium can be increased as compared to the ethylene glycol antifreeze solution. As a result, the flow rate of the low-temperature heat transfer medium can be increased, and the heat transfer efficiency of the low-temperature heat transfer medium can be further improved. Further, by improving the heat transfer efficiency of the low-temperature heat transfer medium, it is possible to improve the heat transfer efficiency of the entire system including the external heat exchanger 36.

Further, by using the carboxylate aqueous solution as the low-temperature heat transfer medium, the heat exchange efficiency of the low-temperature heat transfer medium can be improved, and the cooling at the coolers 37 to 39 can be improved. Therefore, the required cooling capacity can be secured even in a configuration that causes the heat transfer resistance to increase such as a configuration where the partition wall 43 is disposed between the battery 33 and the first cooler 37. Alternatively, when such a configuration in which the heat transfer resistance is increased is not used, the coolers 37 to 39 can be downsized.

Further, in the present embodiment, the proportion of water relative to the carboxylate aqueous solution is 50% or more. The carboxylate aqueous solution can maintain a higher proportion of water while having a lower freezing point as compared to an ethylene glycol-based antifreeze solution. Therefore, by increasing the proportion of water with a large heat capacity in the carboxylate aqueous solution, the heat capacity of the low-temperature heat transfer medium can be increased, and the thermal conductivity can be further increased.

Furthermore, by increasing the proportion of water in the carboxylate aqueous solution, the viscosity of the low-temperature heat transfer medium can be further lowered. Further, by increasing the proportion of water in the carboxylate aqueous solution, the cost of the low-temperature heat transfer medium can be reduced.

The present disclosure is not limited to the embodiments described above, and various modifications can be made as follows within a range not departing from the spirit of the present disclosure. Further, means disclosed in the above embodiments may be appropriately combined within an enabling range.

For example, the low-temperature heat transfer medium of the above embodiment may contain other additives such as an antioxidant and a rust inhibitor, if necessary.

Further, in the above embodiment, the partition wall 43 is disposed between the battery 33 and the first cooler 37. However, the partition wall 43 may not be disposed and the battery 33 and the first cooler 37 may be in direct contact with each other.

Further, in the above embodiment, the carboxylate aqueous solution is used as the low-temperature heat transfer medium in the low-temperature medium circuit 30, but the present disclosure is not necessarily limited to this, and the carboxylate aqueous solution may be used as the high-temperature heat transfer medium in the high-temperature medium circuit 20. In this case, the same heat transfer medium can be shared between the high-temperature medium circuit 20 and the low-temperature medium circuit 30.

While the present disclosure has been described with reference to embodiments thereof, it is to be understood that the disclosure is not limited to the embodiments and constructions. The present disclosure encompasses various modifications and variations within the scope of equivalents. In addition, while the various combinations and configurations, which are preferred, other combinations and configurations, including more, less or only a single element, are also within the spirit and scope of the present disclosure.

1. A heat transfer medium for a heat transfer system including a refrigerant cycle device through which a refrigerant circulates and a heat transfer medium circuit having a cooling target device, the medium comprising:
a carboxylate aqueous solution formed by dissolving carboxylate in water, wherein
the carboxylate aqueous solution is cooled through heat exchange with the refrigerant and absorbs heat from the cooling target device while circulating through the heat transfer medium circuit.

2. The heat transfer medium according to claim 1, wherein
a carboxylic acid constituting the carboxylate is at least one of formic acid, acetic acid, and propionic acid.

3. The heat transfer medium according to claim 1, wherein
a metal constituting the carboxylate is an alkali metal.

4. The heat transfer medium according to claim 3, wherein
the alkali metal is at least one of potassium and sodium.

5. A heat transfer system, comprising:
a heat transfer medium circuit through which the heat transfer medium according to claim 1 circulates;
a refrigeration cycle device through which a refrigerant circulates;
a cooling heat exchanger that cools the heat transfer medium through heat exchange between the refrigerant and the heat transfer medium; and
a cooling target device disposed in the heat transfer medium circuit, the heat transfer medium absorbing heat from the cooling target device.

6. The heat transfer system according to claim 5, further comprising:
a high-temperature heat transfer medium circuit through which a high-temperature heat transfer medium having a temperature higher than that of the heat transfer medium circulates; and
a heating heat exchanger that heats the high-temperature heat transfer medium through heat exchange between the refrigerant and the high-temperature heat transfer medium, wherein
the high-temperature heat transfer medium is the carboxylate aqueous solution.

7. The heat transfer system according to claim 5, further comprising:
a cooler through which the heat transfer medium flows; and
a partition wall that separates the cooling target device from the cooler, wherein
the cooling target device is an electric device that operates with electricity, and
the heat transfer medium flowing through the cooler exchanges heat with the electric device via the partition wall.
